(19) United States
(12) Patent Application Publication
(10) Pub. No.: US 2009/0206389 A1
(43) Pub. Date: Aug. 20, 2009

(54) NONVOLATILE MEMORY DEVICE AND METHOD OF MANUFACTURING THE SAME

(76) Inventor: Masayuki Masukawa, Miyagi (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/206,155

(22) Filed: Sep. 8, 2008

(30) Foreign Application Priority Data
Feb. 14, 2008 (JP) 2008033383

(51) Int. Cl. H01L 29/792; H01L 21/336

(52) U.S. Cl. 257/324; 438/287; 257/E29.309; 257/E21.423

(57) ABSTRACT

A nonvolatile memory device which contributes to improvement of electrical erase characteristics and a method of manufacturing the same are provided. The nonvolatile memory device includes a semiconductor substrate, a gate electrode formed on the semiconductor substrate, a diffusing layer electrode formed adjacent to the gate electrode on the semiconductor substrate; a charge accumulating layer formed on a lateral side of the gate electrode and retaining injected electrons, and an LDD region formed below the diffusing layer electrode. The charge accumulating layer is formed on only the lateral side of the gate electrode and does not extend along the LDD region.

### CROSS-REFERENCE TO RELATED APPLICATIONS

This application is a claims priority under 35 U.S.C. §119 to Japanese Patent Application Serial No. JP2008-033383 filed on Feb. 14, 2008, entitled “NONVOLATILE MEMORY DEVICE AND METHOD OF MANUFACTURING THE SAME,” the disclosure of which is hereby incorporated by reference.

### RELATED ART

### Field of the Invention

The present invention relates to a structure of a nonvolatile memory device and a method of manufacturing the nonvolatile memory device and, more particularly, to a structure of a memory cell transistor in a nonvolatile memory with a nitride film as a charge retention film.

A metal oxide nitride oxide semiconductor (MONOS) structure is a known nonvolatile semiconductor memory device. In the MONOS structure, for example, an oxide-nitride-oxide (ONO) film is provided between a substrate and a gate electrode. Charges can be captured and accumulated using a large number of traps existing in the nitride part of the ONO film. Drawing charges into or out of these traps allows a nonvolatile semiconductor memory device to exhibit its own function.

As far as methods for drawing into or out charges are concerned, there is a method of performing a write and erase operation by drawing electrons into or out of the entire surface below a gate electrode using a tunnel current and a method of using hot carriers. The method of using the tunnel current of electrons allows a rewritable operation to be performed many times, thereby securing high reliability. On the other hand, the method of using the hot carriers allows an operating voltage for write and erase to be lowered (hence leading to low production costs) and further allows a write and erase operation to be performed at a high speed.

FIG. 1 is a sectional view showing a conventional nonvolatile semiconductor memory device 100. The conventional nonvolatile semiconductor memory device 100 has a nitride film 110 serving as a charge retention film. The conventional nonvolatile semiconductor memory device 100 includes a semiconductor substrate 108, a gate oxide film 107 formed on the semiconductor substrate 108, and a gate electrode 105 formed on the gate oxide film 107. An lightly doped drain (LDD) region 114 and a diffusing layer 101 are formed in a surface of the semiconductor substrate 108. A mask oxide film 106 and a nitride film 110 are formed in a lateral side of the gate electrode (control gate) 105. A side wall 109 is formed on an outer sides of the nitride film 110. A contact plug (diffusing layer electrode) 112 is formed near the gate electrode 105 on the semiconductor substrate 108.

In manufacturing the nonvolatile semiconductor memory device 100 as described above, according to any technique known in the art, the control gate 105 is formed, and then the mask oxide film 106 and the nitride film 110 are formed on the semiconductor substrate 108 and a side wall of the control gate 105. Next, a nitride wall 109 is formed on the lateral side of the control gate 105 according to any technique known in the art. Thus, the mask oxide film 106 and the nitride film 110 are present between the control gate 105 and the side wall 109. In addition, the contact plug 112 is formed to be less than 100 nm from the adjacent gate electrode 105 using a self-aligned contact (SAC) structure known in the art. Regions in the nitride film 110 in which charges are accumulated are on both sides of the control gate 105, and a two-bit write operation is controlled by one of the control gates 105.

In the write operation of the nonvolatile semiconductor memory device 100, both diffusing layers 101, 102 are biased with 6 V and 0 V, respectively, and a voltage of 10 V is applied to the control gate 105. Some of electrons supplied from the diffusing layer 102 serving as a source are injected, as hot channel electrons, into the charge accumulating nitride film 110 at the side of the diffusing layer 101. Conversely, when electrons are injected into the charge accumulating nitride film 110 at the side of the diffusing layer 102, a bias to the diffusing layer 102 may be reverse to that of the diffusing layer 101.

In an electrical erase operation, a voltage of 6 V is applied to the diffusing layers, 101, 102 and a voltage of −6 V is applied to the control gate 105. Hot holes generated near the diffusing layers are injected into the charge accumulating nitride film 110 by an electrical field of the control gate 105. This allows electrons trapped in the charge accumulating nitride film 110 to be electrically cancelled, thereby completing the electrical erasing operation.

The electrical write operation is performed by hot channel electrons injected into the charge accumulating nitride film 110 while the electrical erase operation is performed by hot channel holes injected into the charge accumulating nitride film 110. That is, the electrical write operation is different in principle from the electrical erase operation. With decreased distances between the gate electrode 105 and the diffusing layer electrode 112 as a result of miniaturization, particularly when the diffusing layer electrode 112 is formed with a SAC structure, a distribution of injection of electrons/holes into the charge accumulating film may vary depending greatly on the electrical field of the diffusing layer electrode 112.

If a distance between the gate electrode 105 and the diffusing layer electrode 112 is large (i.e., more than 100 nm), electrons generated at a border of the diffusing layer are injected into a portion of the charge accumulating nitride film 110, which is near the gate electrode 105 under an effect of the gate electrode 105 (see FIG. 2). Likewise, holes generated at a border of the diffusing layer are injected into a portion of the charge accumulating nitride film 110, which is near the gate electrode 105, thereby allowing efficient electrical erase (see FIG. 3).

On the contrary, if a distance between the gate electrode 105 and the diffusing layer electrode 112 decreases (less than 100 nm) by using a SAC structure or the like, electrons generated near a boundary between the diffusing layer and the substrate 108 are widely distributed in a horizontal direction of the charge accumulating nitride film 110 under an effect of the diffusing layer electrode 112 (see FIG. 4). On the other hand, holes repulsive against an electric field of the diffusing layer are injected into a portion of the charge accumulating nitride film 110, which is closer to the gate electrode 105 (see FIG. 5). This may lead to a difference in injection distribution between electrons and holes, which may result in incomplete electrical erasure with some electrons left (see FIG. 6). This incomplete electrical erasure causes remarkable deterioration of electrical erase characteristics.

### INTRODUCTION TO THE INVENTION

The present invention includes a nonvolatile memory device which contributes to improvement of electrical erase characteristics, and a method of manufacturing the same.

In accordance with a first aspect of the invention, there is provided a nonvolatile memory device including: a semiconductor substrate; a gate electrode formed on the semiconductor substrate; a diffusing layer electrode formed adjacent to the gate electrode on the semiconductor substrate; a charge accumulating layer formed on a lateral side of the gate electrode and retaining injected electrons; and an LDD region formed below the diffusing layer electrode. The charge accumulating layer is formed to extend vertically on the lateral side of the gate electrode and does not extend horizontally along the LDD region.

The diffusing layer electrode may be formed by means of, for example, a SAC process, and then a distance between the gate electrode and the diffusing layer electrode is preferably set to be less than 100 nm.

According to a second aspect of the invention, there is provided a method of manufacturing a nonvolatile memory device, including the steps of: forming a gate electrode on a semiconductor substrate; forming an LDD region in a surface of the semiconductor substrate; forming a charge accumulating layer on a surface of the gate electrode; etching the charge accumulating layer in such a manner that the charge accumulating layer is formed to extend vertically on a lateral side of the gate electrode and does not extend horizontally along the LDD region; and forming a diffusing layer electrode adjacent to the gate electrode.

It is a first aspect of the present invention to provide a

In a more detailed embodiment of the first aspect. In yet another more detailed embodiment. In a further detailed embodiment. In still a further detailed embodiment. In a more detailed embodiment. In a more detailed embodiment. In another more detailed embodiment. In yet another more detailed embodiment. In still another more detailed embodiment.

In yet another more detailed embodiment of the first aspect. In still another more detailed embodiment. In a further detailed embodiment. In still a further detailed embodiment. In a more detailed embodiment. In a more detailed embodiment. In another more detailed embodiment. In yet another more detailed embodiment.

It is a second aspect of the present invention to provide a.

It is a third aspect of the present invention to provide a

It is a fourth aspect of the present invention to provide a.

As used herein, the phrase “the charge accumulating layer is formed on only a lateral side of the gate electrode and does not extend along the LDD region” is intended to refer to a charge accumulating layer having a structure that it is formed in only the lateral side of the gate electrode and does not extend beyond its thickness along a substrate surface (the LDD region).

As described above, in the structure of the conventional memory device, when a distance between electrodes approximates less than 100 nm by using a SAC structure or the like, electrons are injected in the charge accumulating layer above the LDD region. On the contrary, in the structure of the memory device of the present invention, a portion of the charge accumulating layer into which electrons are injected can be restricted to only the lateral side of the gate electrode. That is, the memory device of the present invention has the structure having no horizontally extending charge accumulating layer existing above the LDD region. With this structure, it is possible to make an injection distribution of electrons coincide with an injection distribution of holes and perform an electrical erase operation with high efficiency.

### BRIEF DESCRIPTION OF THE DRAWINGS

FIG. 1 is a sectional view showing a structure of a conventional nonvolatile semiconductor memory device.

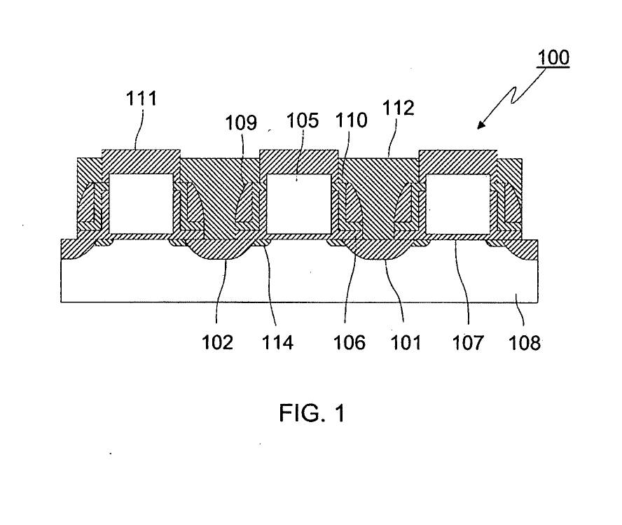

FIG. 2 is a sectional view showing a write operation (principle) of a conventional nonvolatile semiconductor memory device having a gate electrode spaced more than 100 nm from a diffusing layer electrode.

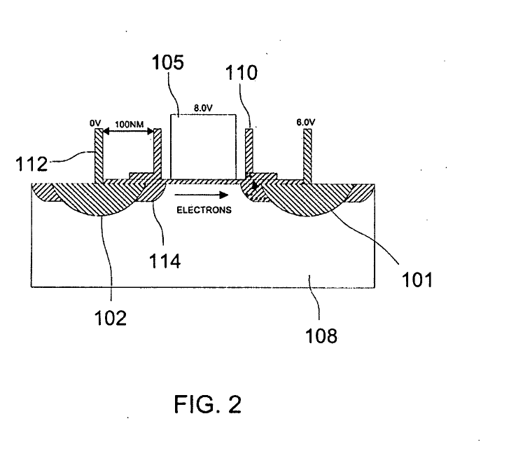

FIG. 3 is a sectional view showing an erase operation (principle) of a conventional nonvolatile semiconductor memory device having a gate electrode spaced more than 100 nm from a diffusing layer electrode.

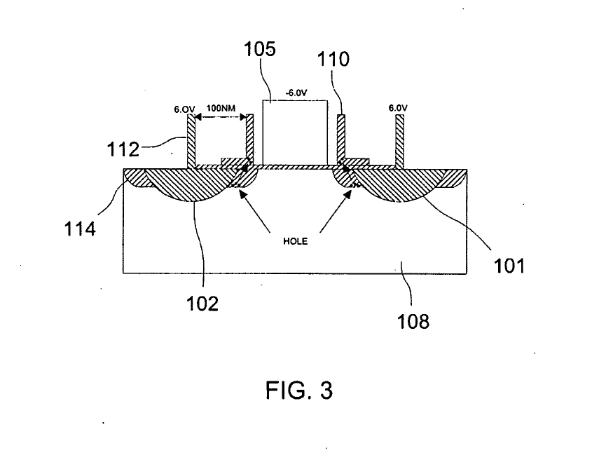

FIG. 4 is a sectional view showing a write operation (principle) of a conventional nonvolatile semiconductor memory device having a gate electrode spaced less than 100 nm from a diffusing layer electrode.

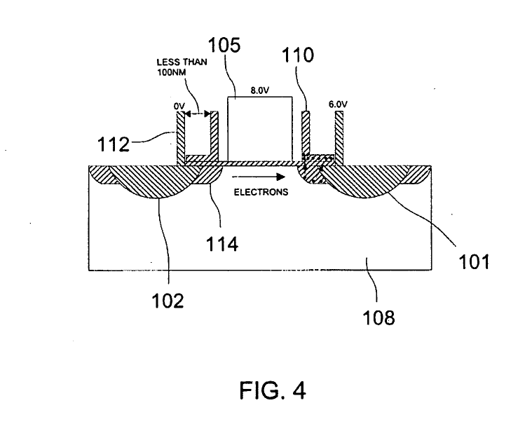

FIG. 5 is a sectional view showing an erase operation (principle) of a conventional nonvolatile semiconductor memory device having a gate electrode spaced less than 100 nm from a diffusing layer electrode.

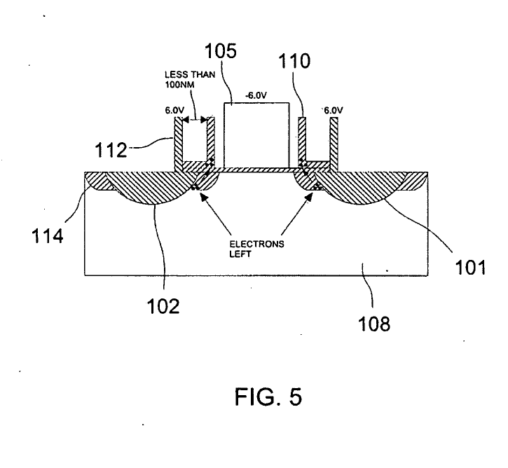

FIG. 6 is a sectional view showing a state after erase of a conventional nonvolatile semiconductor memory device having a gate electrode spaced less than 100 nm from a diffusing layer electrode.

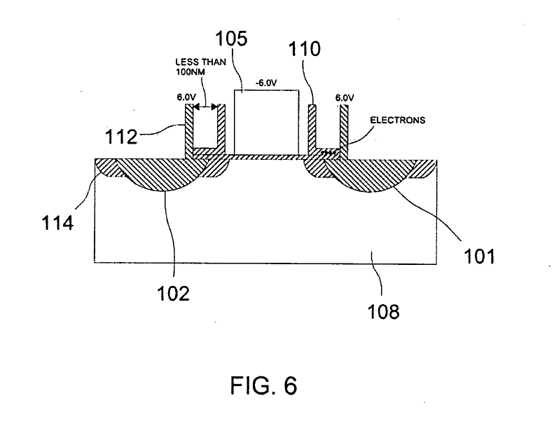

FIG. 7 is a sectional view showing a structure of a nonvolatile semiconductor memory device according to a first exemplary embodiment of the present invention.

FIG. 8 is a sectional view showing a portion of a process of manufacturing a nonvolatile semiconductor memory device according to a second exemplary embodiment of the present invention.

FIG. 9 is a sectional view showing a portion of a process of manufacturing a nonvolatile semiconductor memory device according to the second exemplary embodiment of the present invention.

FIG. 10 is a sectional view showing a portion of a process of manufacturing a nonvolatile semiconductor memory device according to the second exemplary embodiment of the present invention.

FIG. 11 is a sectional view showing a portion of a process of manufacturing a nonvolatile semiconductor memory device according to the second exemplary embodiment of the present invention.

FIG. 12 is a sectional view showing a portion of a process of manufacturing a nonvolatile semiconductor memory device according to the second exemplary embodiment of the present invention.

FIG. 13 is a sectional view showing a portion of a process of manufacturing a nonvolatile semiconductor memory device according to the second exemplary embodiment of the present invention.

FIG. 14 is a sectional view showing a portion of a process of manufacturing a nonvolatile semiconductor memory device according to the second exemplary embodiment of the present invention.

FIG. 15 is a sectional view showing a portion of a process of manufacturing a nonvolatile semiconductor memory device according to the second exemplary embodiment of the present invention.

FIG. 16 is a sectional view showing a structure of a nonvolatile semiconductor memory device according to the exemplary embodiment of the present invention.

FIG. 17 is a sectional view showing a write operation (principle) of a nonvolatile semiconductor memory device according to the present invention.

FIG. 18 is a sectional view showing an erase operation (principle) of a nonvolatile semiconductor memory device according to the present invention.

FIG. 19 is a sectional view showing a state after erase of a nonvolatile semiconductor memory device according to the present invention.

### DETAILED DESCRIPTION

The exemplary embodiments of the present invention are described and illustrated below to encompass fabrication of a nonvolatile memory device and, more particularly, to fabrication of a memory cell transistor in a nonvolatile memory with a nitride film as a charge retention film, as well as the resulting product thereof. Of course, it will be apparent to those of ordinary skill in the art that the preferred embodiments discussed below are exemplary in nature and may be reconfigured without departing from the scope and spirit of the present invention. However, for clarity and precision, the exemplary embodiments as discussed below may include optional steps, methods, and features that one of ordinary skill should recognize as not being a requisite to fall within the scope of the present invention.

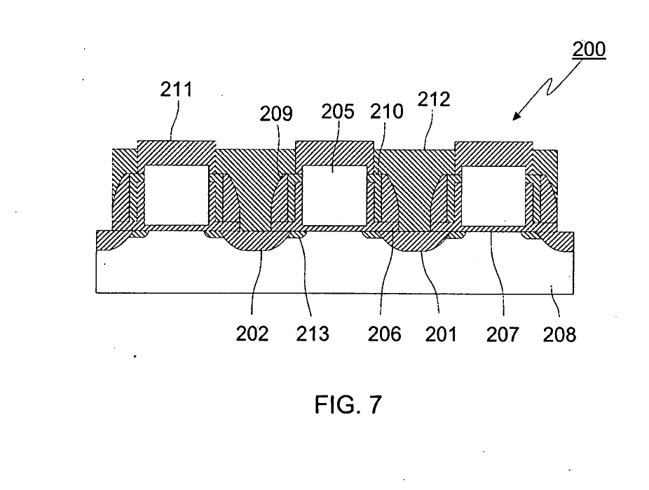

Referencing FIG. 7, a nonvolatile semiconductor memory device 200 according to a first exemplary embodiment of the present invention includes a nitride film 210 serving as a charge retention film. The nonvolatile semiconductor memory device 200 includes a semiconductor substrate 208, a gate oxide film 207 formed on the semiconductor substrate 208, and a gate electrode 205 formed on the gate oxide film 207. A lightly doped drain region 213 and a diffusing region 202 are formed in a surface of the semiconductor substrate 208. A mask oxide film 206 and a nitride film 210 are formed on the lateral sides of the gate electrode (control gate) 205. A side wall 209 is formed on an outer side of the nitride film 210. A contact plug (diffusing layer electrode) 212 is formed near the gate electrode 205 on the semiconductor substrate 208.

A charge accumulating layer (nitride film) 210 is formed vertically along the lateral side of the gate electrode 205 without extending horizontally along the lightly doped drain region 213. That is, in this exemplary embodiment, the charge accumulating layer 210 has a structure that it is formed in only the lateral side of the gate electrode 205 and does not extend beyond its thickness along a substrate surface (i.e., the lightly doped drain region 213).

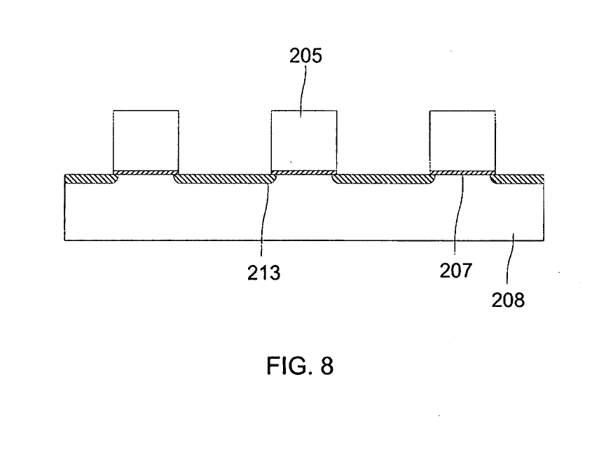

Now, a process of manufacturing a second nonvolatile semiconductor memory device 200′ will be described with reference to FIGS. 8 to 16. Referring first to FIG. 8, the gate oxide film 207 is formed on the entire surface of the semiconductor substrate 208. Next, a film for forming the control gate 205 (optionally fabricated from polysilicon or the like) is formed on the gate oxide film 207 and is patterned to form the control gate 205. Subsequently, the lightly doped drain region 213 is formed by means of an implantation process.

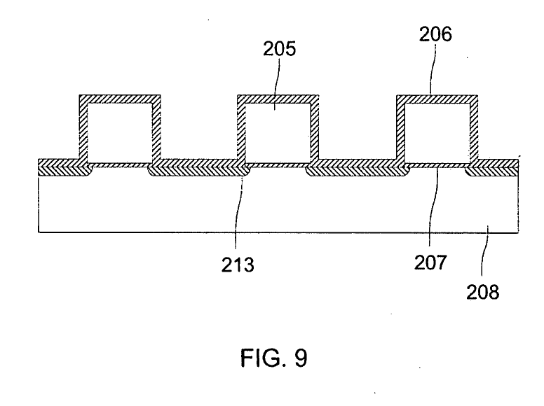

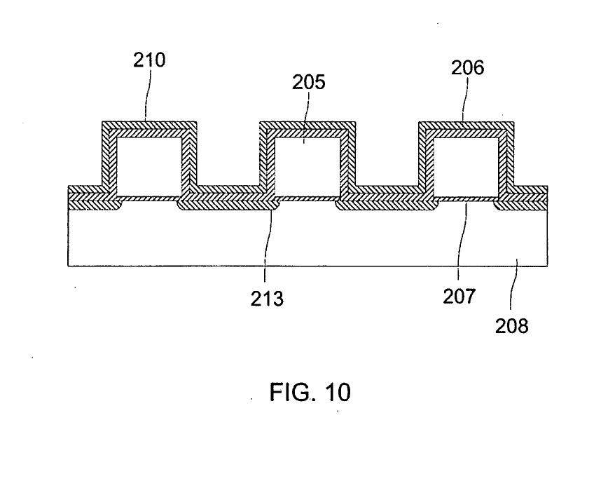

Next, as shown in FIG. 9, the mask oxide film 206 is formed on the entire exposed surfaces of the semiconductor substrate 208 and control gate 205. Subsequently, as shown in FIG. 10, the charge accumulating film 210 is formed on the mask oxide film 206.

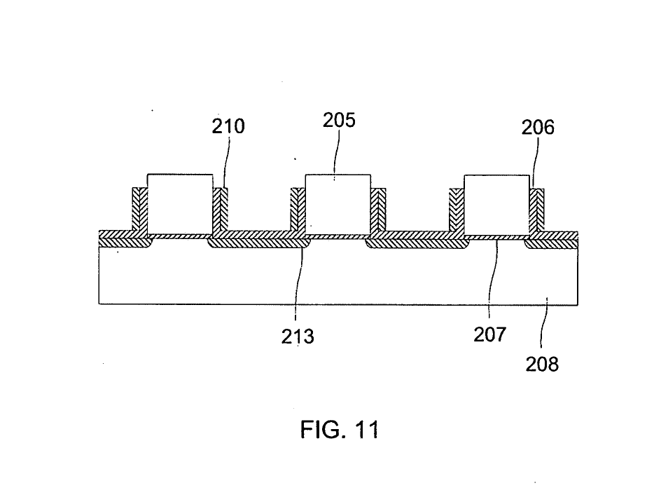

Thereafter, as shown in FIG. 11, the charge accumulating film 210 and mask oxide film 206 are etched so that the charge accumulating film 210 is left on the lateral sides of the gate electrodes 205 and the mask oxide film is removed from the top of the control gate 205. In this exemplary embodiment, the charge accumulating film 210 is dry-etched under a condition in which an etching rate in a direction perpendicular to the semiconductor substrate 208 is higher than that in a direction in parallel to the semiconductor substrate 208.

If the etching rate in the direction in parallel to the wafer is too high, the nitride film 210 on the lateral sides of the gate electrode 205 may be removed before the horizontal aspects of the nitride film 210 are completely removed, and thus the nitride film 210 in the lateral sides of the gate electrode 205 may become too thin. On the contrary, if the etching rate in the direction perpendicular to the wafer is too high, after the horizontal aspects of the nitride film 210 are completely removed, the semiconductor substrate 208 below the bottom of the nitride film 210 may be disadvantageously etched. For example, an etching operation may be performed for 10 seconds or so using trifluoromethane (CHF₃), tetrafluoromethane (CF₄), oxygen (O₂) or argon (Ar) gas with RF power of approximately 100 W. An exemplary technique for use with the instant invention to form such a SAC structure is disclosed in Japanese Patent No. 2002-508589, the disclosure of which is hereby incorporated by reference.

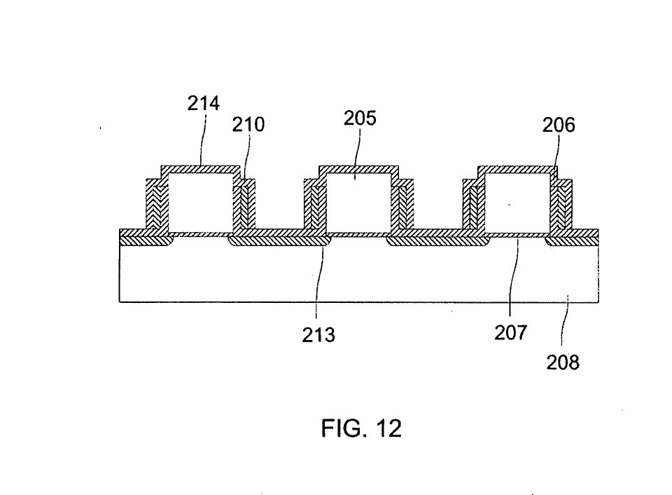

Next, as shown in FIG. 12, an oxide film (TOP oxide film) 214 is formed on the entire surface and thereafter etched to remove the horizontal portions of the mask oxide film 206 directly over the lightly doped drain region 213.

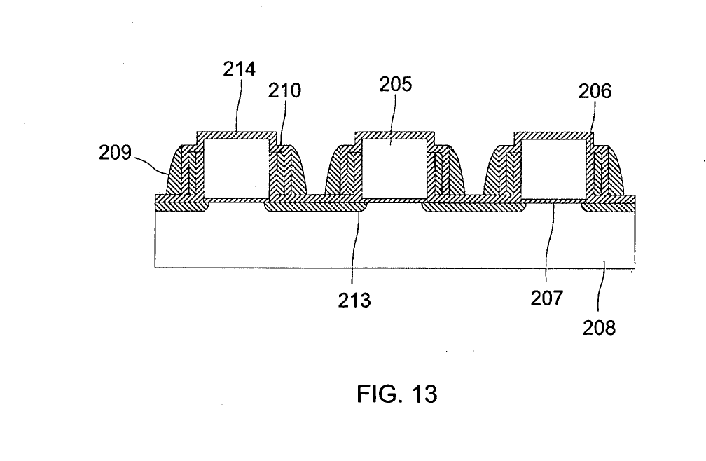

Referring to FIG. 13, a nitride film is deposited on the oxide film 214 and is etched in such a manner that it is left on only the lateral sides of the gate electrode 205, thereby forming the side walls 209. In this embodiment, the nitride film is dry-etched under a condition in which an etching rate in a direction perpendicular to the semiconductor substrate 208 is higher than that in a direction in parallel to the semiconductor substrate 208.

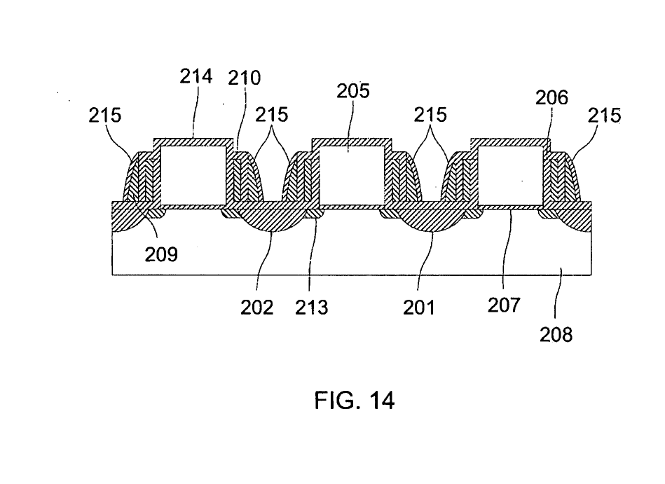

Next, as shown in FIG. 14, the diffusing layers 201, 202 are formed by a conventional implantation process. Subsequently, a stopper film 215 for forming a contact hole is formed on the exposed surfaces of the side walls 209.

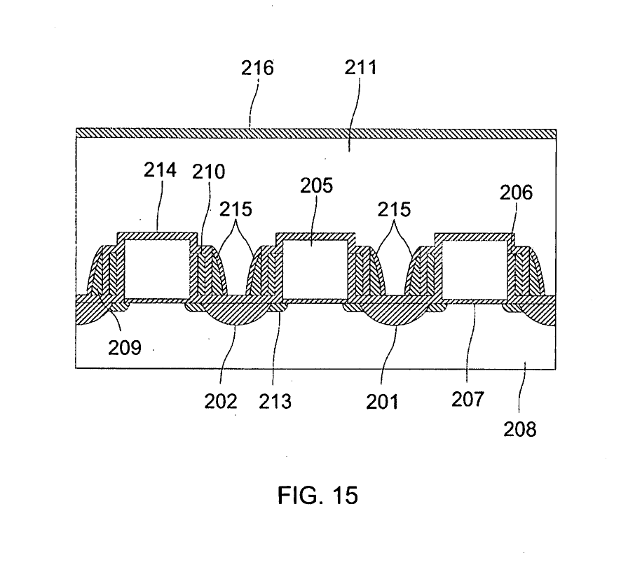

Subsequently, as shown in FIG. 15, an interlayer insulating film 211 is formed over the entire surface. Following formation of the interlayer insulating film 211, a CAP film 216 is formed over the interlayer insulating film 211.

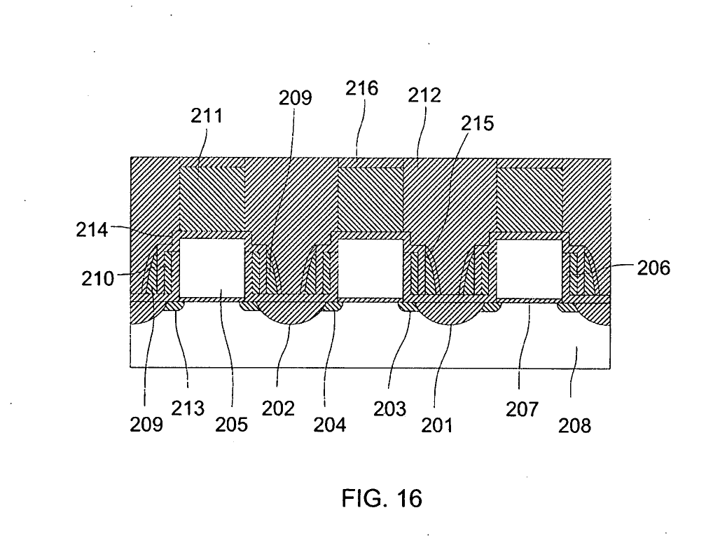

Referring to FIG. 16, contact holes are formed at a position at which a contact plug is to be formed by means of a photolithographic process and an etching process. Thereafter, the contact holes are filled with a conductive material to form contact plugs 212. The contact plugs 212 may be formed less than 100 nm from the adjacent gate electrode 205 using a SAC (Self Aligned Contact) structure known in the art.

Following the above description, those skilled in the art would readily understand the modifications necessary to fabricate the first exemplary embodiment 200 shown in FIG. 7.

Pursuant to the structure disclosed as the first and second exemplary embodiments 200, 200′, a single control gate 205 controls those regions in the nitride film 210 in which charges are accumulated, as well as a two-bit write operation.

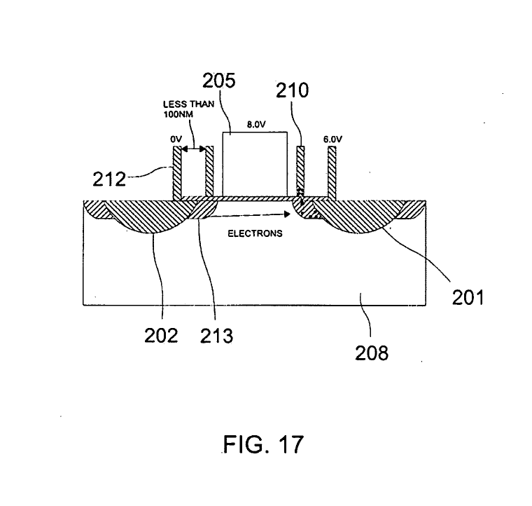

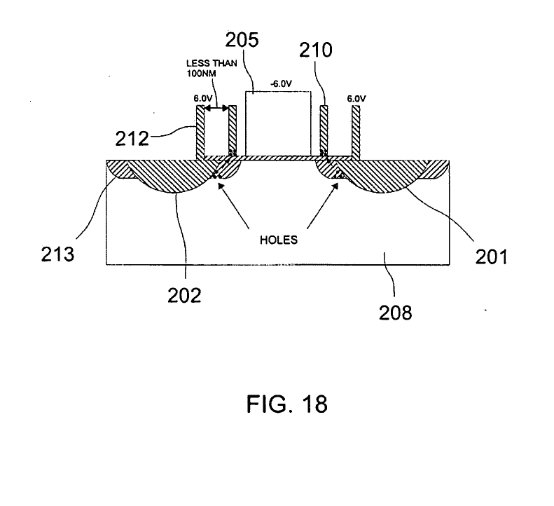

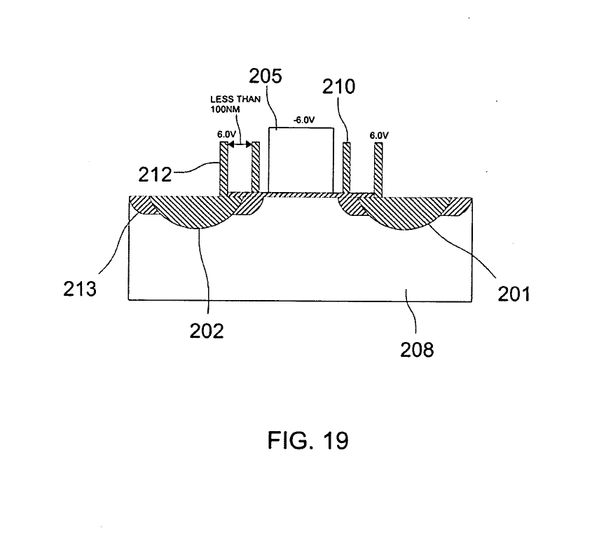

FIG. 17 is a sectional view showing a write operation (principle) of the nonvolatile semiconductor memory device according to the present invention. FIG. 18 is a sectional view showing an erase operation (principle) of the nonvolatile semiconductor memory device according to the present invention. FIG. 19 is a sectional view showing a state after erase of the nonvolatile semiconductor memory device according to the present invention.

Referring to FIG. 17, in a write operation of the nonvolatile semiconductor memory device as constructed according to the instant invention, the diffusing layer 201 and the diffusing layer 202 are biased with 6 V and 0 V, respectively, and a voltage of 8 V is applied to the control gate 205. Some of electrons supplied from the diffusing layer 202 serving as a source are injected, as hot channel electrons, into the charge accumulating nitride film 210 at the side of the diffusing layer 201. Conversely, when electrons are injected into the charge accumulating nitride film 210 at the side of the diffusing layer 202, a bias to one diffusing layer 202 may be reverse to that of the other diffusing layer 201.

In an electrical erase operation, as shown in FIG. 18, a voltage of 6 V is applied to both diffusing layers 201, 202 and a voltage of −6 V is applied to the control gate 205. Hot holes generated near the diffusing layers are injected into the charge accumulating nitride film 210 by an electrical field of the control gate 205. This allows electrons trapped in the charge accumulating nitride film 210 to be electrically cancelled, thereby completing the electrical erasing operation.

At this stage, the injection of electrons into the charge accumulating nitride film 210 is effected by hot channel electrons injected during the electrical write operation, while the injection of holes into the charge accumulating nitride film 210 is effected by hot channel holes injected during the electrical erase operation. Thus, the principle of injection of the former and that of the latter is apparently different from one another. As a result of decreasing distances between the gate electrode 205 and the diffusing layer electrode 212 with a miniaturization, particularly when the diffusing layer electrode 212 is formed with a SAC structure, a distribution of injected electrons/holes into the charge accumulating film may be changed depending greatly on an effect of electrical field of the diffusing layer electrode 212.

In the aforementioned exemplary embodiments, since the charge accumulating nitride film 210 extends vertically along the lateral side of the gate electrode 205, and not horizontally along the lightly doped drain region 213, electrons are injected into a limited portion of the charge accumulating nitride film 210, as shown in FIGS. 17 and 18. This allows an injection distribution of electrons to be coincident with an injection distribution of holes, thereby making it possible to efficiently cancel the injected electrons, which may result in improved electrical erase characteristics, as shown in FIG. 19.

In a read operation of the aforementioned exemplary semiconductor memory device, presuming both two bits of one cell are blank, two diffusing layer electrodes 212 with a cell interposed therebetween become a source and a drain, respectively, and a channel is turned on by a voltage applied to the gate electrode 205, thereby flowing current through the channel. On the other hand, in a condition where electrons are injected (written) into one of the two bits of one cell, when reading the electron-written bit, the diffusing layer electrode 210 on a side of the electron-written bit becomes a source while the diffusing layer electrode 210 on a side of an electron-not-written bit becomes a drain. In this case, a depletion layer is formed in a channel at a side of the source by an effect of an electric field produced by the injected electrons, thereby preventing current from flowing through the channel. Conversely, when reading the electron-not-written bit, the diffusing layer electrode 210 at a side of the electron-not-written bit becomes a source while the diffusing layer electrode 210 at a side of the electron-written bit becomes a drain, and thus an effect of an electric field produced by the injected electrons is cancelled by a drain voltage, thereby making it possible to flow current through the channel.

Following from the above description and invention summaries, it should be apparent to those of ordinary skill in the art that, while the methods and apparatuses herein described constitute exemplary embodiments of the present invention, the invention contained herein is not limited to this precise embodiment and that changes may be made to such embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the invention disclosed herein in order to fall within the scope of any claims, since the invention is defined by the claims and since inherent and/or unforeseen advantages of the present invention may exist even though they may not have been explicitly discussed herein.

What is claimed is:

1. A nonvolatile memory device comprising:
a semiconductor substrate;
a gate electrode formed over the semiconductor substrate;
a contact formed over the semiconductor substrate and proximate to the gate electrode;
a charge accumulating layer for retaining injected electrons, the charge accumulating layer formed on a lateral side of the gate electrode; and
a doped region formed below the contact;
wherein the charge accumulating layer extends vertically along the lateral side of the gate electrode and does not extend horizontally along the doped region.

2. The nonvolatile memory device according to claim 1,
wherein a distance between the gate electrode and the contact is less than 100 nm.

3. The nonvolatile memory device according to claim 2,
wherein a data write operation and a data erase operation are performed by injection of electrons and injection of holes, respectively.

4. The nonvolatile memory device according to claim 2,
wherein the contact is formed by means of a self-aligned contact process.

5. The nonvolatile memory device according to claim 1,
wherein the contact is formed by means of a self-aligned contact process.

6. The nonvolatile memory device according to claim 1,
wherein a data write operation and a data erase operation are performed by injection of electrons and injection of holes, respectively.

7. The nonvolatile memory device according to claim 1,
wherein the doped region is a lightly doped region.

8. The nonvolatile memory device according to claim 1,
wherein a data write operation and a data erase operation are performed by injection of electrons and injection of holes, respectively.

9. The nonvolatile memory device according to claim 2,
wherein a data write operation and a data erase operation are performed by injection of electrons and injection of holes, respectively.

10. The nonvolatile memory device according to claim 1,
wherein a horizontal thickness of the charge accumulating layer is less than a horizontal thickness of the doped region.

11. A method of manufacturing a nonvolatile memory device, comprising the steps of:
forming a gate electrode on a semiconductor substrate;
forming a doped region within the semiconductor substrate;
forming a charge accumulating layer over the gate electrode;
etching the charge accumulating layer so that the charge accumulating layer remains on a lateral side of the gate electrode and does not extend horizontally along the doped region; and
forming a contact to be in electrical communication with the doped region.

12. The method of claim 11,
wherein a distance between the gate electrode and the diffusing layer electrode is less than 100 nm.

13. The nonvolatile memory device according to claim 12,
wherein the diffusing layer electrode is formed by means of a self-aligned contact process.

14. The nonvolatile memory device according to claim 11,
wherein a thickness of the charge accumulating layer is less than a thickness of the doped region.

15. The nonvolatile memory device according to claim 11,
wherein the doped region is a lightly doped region.

16. The nonvolatile memory device according to claim 11,
wherein the diffusing layer electrode is formed by means of a self-aligned contact process.

17. A nonvolatile memory device comprising:
a semiconductor substrate;
a gate electrode formed over the semiconductor substrate;
a contact formed in proximity to the gate electrode and over the semiconductor substrate;
a charge accumulating layer formed on a lateral side of the gate electrode, the charge accumulating layer including a vertical portion substantially uniformly spaced from the gate electrode, the vertical portion having a substantially uniform thickness and a lower end with substantially the same thickness; and
a doped region formed within the semiconductor substrate, where the contact is ultimately above the doped region;
wherein the lower end of the charge accumulating layer is proximate the doped region.

18. The nonvolatile memory device of claim 17, further comprising a sidewall spacer interposing the contact plug and charge accumulating layer proximate the doped region.

19. The nonvolatile memory device of claim 18, further comprising an oxide layer interposing the charge accumulating layer and the gate electrode.

20. The nonvolatile memory device of claim 19, wherein the oxide layer physically separates the charge accumulating layer from the gate electrode.

21. The nonvolatile memory device of claim 18, wherein the sidewall spacer physically separates the charge accumulating layer from the contact plug.

22. The nonvolatile memory device of claim 18, wherein the sidewall spacer includes an etch stop layer for contact plug formation.

23. The nonvolatile memory device according to claim 17,
wherein a distance between the gate electrode and the contact is less than 100 nm.

24. The nonvolatile memory device according to claim 17,
wherein the contact is formed by means of a self-aligned contact process.

25. The nonvolatile memory device according to claim 17,
wherein the substantially uniform thickness of the vertical portion of the charge accumulating layer is less a width of the doped region.

26. The nonvolatile memory device according to claim 17,
wherein the doped region is a lightly doped region.
